(19) United States
(12) Patent Application Publication
(10) Pub. No.: US 2026/0218026 A1
(43) Pub. Date: Jul. 30, 2026

(54) POLISHING SOLUTION AND SURFACE TREATMENT METHOD

(71) Applicant: GeneMind Biosciences Co., Ltd., Shenzhen (CN)

(72) Inventors: Dezhi Zeng, Shenzhen (CN); Wenbing Wang, Shenzhen (CN); Zhifeng Lin, Shenzhen (CN); Xinlin Yang, Shenzhen (CN); Jiaqiang Gu, Shenzhen (CN); Wenxin Chen, Shenzhen (CN); Linsen Li, Shenzhen (CN); Fang Chen, Shenzhen (CN)

(21) Appl. No.: 19/143,973

(22) PCT Filed: Dec. 28, 2023
(86) PCT No.: PCT/CN2023/142604

§ 371 Date: Jun. 27, 2025

(30) Foreign Application Priority Data
Dec. 30, 2022 (CN) 202211723073.4

(51) Int. Cl. C09K 3/14

(52) U.S. Cl. CPC C09K 3/1463

(57) ABSTRACT

Provided in the present application are a polishing solution and a surface treatment method. The method comprises: using a polishing solution to act on a substrate having a surface bonded to a first polymer, so as to remove the first polymer on at least part of the surface of the substrate, wherein the polishing solution comprises a polishing material, and the polishing material is selected from at least one of a second polymer and an inorganic nanomaterial. Using the surface treatment method of the present application can effectively polish the soft material on the surface of the substrate, thus avoiding damages or corrosion to the substrate, reducing abrasive residues, having easy and convenient operation and low costs, and being suitable for wide use.

The present application claims priority to Chinese Patent Application No. 202211723073.4 filed to China National Intellectual Property Administration on Dec. 30, 2022, and entitled “POLISHING SOLUTION AND SURFACE TREATMENT METHOD FOR SUBSTRATE”, which is incorporated herein by reference in its entirety.

### TECHNICAL FIELD

The present application relates to the field of biochemistry. In particular, the present application relates to a polishing solution and a surface treatment method.

### BACKGROUND

In the process of fabricating semiconductor components into chips, polishing techniques are typically employed to obtain surfaces that are flat, free of scratches, and uncontaminated by impurities. Currently, the most widely used polishing technique is chemical mechanical polishing (CMP). Its primary working mechanism involves the relative motion between the polished substrate and the polishing pad under controlled pressure and polishing solution, enabling gradual layer-by-layer removal of material from the substrate surface. This technique results in a highly planarized substrate surface with low surface roughness and minimal defects.

Currently, most of the existing polishing solutions are polishing solutions developed for inorganic surfaces. For organic surfaces with better flexibility, further investigation is still required to select suitable polishing solutions to obtain flat, scratch-free, and contaminant-free surfaces.

### SUMMARY

It should be noted that the present application has been completed based on the following findings of the inventors:

Soft materials refer to a class of materials primarily composed of polymer substances. Compared to hard materials such as metals or oxide films, polymer materials are characterized by relatively low hardness. Soft materials include polymer films, such as hydrogel films, which may be used in semiconductor devices. For example, on microfluidic chips, soft materials can provide a microenvironment that simulates the extracellular matrix, thereby facilitating cellular research. On sequencing flow cells, soft materials can be used to immobilize sequencing primers, which in turn enables the immobilization of nucleic acid fragments for sequencing, thereby improving sequencing accuracy.

Currently, existing polishing solutions are mainly suitable for hard materials such as oxide films or metals, but are less effective for polishing soft materials. The use of such polishing solutions on soft materials is prone to issues such as scratching of the substrate, contamination due to abrasive residues on the substrate surface, and corrosion of the substrate material.

In view of this, the inventors have conducted extensive screening and optimization work to obtain a polishing solution particularly suitable for soft material polishing, as well as a method for treating a surface using the polishing solution. Using the polishing solution or the method can efficiently polish soft materials on the surface of a substrate, while avoiding damage or corrosion to the substrate, reducing abrasive residues, and having easy and convenient operation and low costs, thus being suitable for widespread application.

To this end, in a first aspect of the present application, the present application provides a surface treatment method. According to embodiments of the present application, the method includes: using a polishing solution to treat a substrate having a first polymer bound to a surface thereof to remove the first polymer from at least a portion of the surface of the substrate, where the polishing solution includes a polishing agent, and the polishing agent is selected from at least one of a second polymer and an inorganic nanomaterial.

In a second aspect of the present application, the present application provides a polishing solution. According to the embodiments of the present application, the polishing solution is used for treating a surface of a substrate having a first polymer bound to the surface thereof, and the polishing solution includes: a polishing agent, selected from at least one of a second polymer and an inorganic nanomaterial.

In a third aspect of the present application, the present application provides a reagent kit. According to the embodiments of the present application, the reagent kit includes: the polishing solution according to the second aspect of the present application.

In a fourth aspect of the present application, the present application provides a method for preparing a flow cell. According to the embodiments of the present application, the method includes: providing a substrate, where a first polymer is bound to a surface of the substrate; and treating the surface of the substrate having the first polymer bound thereto using the aforementioned surface treatment method according to the first aspect of the present application, or using the polishing solution according to the second aspect of the present application, to remove the first polymer from at least a portion of the surface of the substrate to obtain the flow cell.

In the substrate aspect of the present application, the present application provides a flow cell. According to the embodiments of the present application, the flow cell includes a substrate, and the substrate is a substrate treated by the aforementioned surface treatment method according to the first aspect of the present application, or treated by the polishing solution according to the second aspect of the present application.

The additional aspects and advantages of the present application will be partially set forth in the following description, and will partially become apparent from the following description or be appreciated by practice of the present application.

### BRIEF DESCRIPTION OF THE DRAWINGS

The aforementioned and/or additional aspects and advantages of the present application will become apparent and easily understood from the description of the embodiments with reference to the following drawings, in which:

FIG. 1 is a schematic structural view of a solid substrate according to an embodiment;

FIG. 2 is a schematic structural view of a field of view according to an embodiment;

FIG. 3 is a schematic structural view of a trackline according to an embodiment;

FIG. 4 is another schematic structural view of a trackline according to an embodiment;

FIG. 5 is another schematic structural view of a trackline according to an embodiment;

FIG. 6 is an enlarged schematic view of portion A in FIG. 3;

FIG. 7 is a sequencing image obtained by sequencing using a sequencing flow cell polished with the polishing solution (Example 1);

FIG. 8 is a sequencing image obtained by sequencing using a sequencing flow cell polished with the polishing solution (Example 2);

FIG. 9 is a sequencing image obtained by sequencing using a sequencing flow cell polished with the polishing solution (Example 3);

FIG. 10 is a sequencing image obtained by sequencing using a sequencing flow cell polished with the polishing solution (Example 4);

FIG. 11 is a sequencing image obtained by sequencing using a sequencing flow cell polished with the polishing solution (Example 5);

FIG. 12 is a sequencing image obtained by sequencing using a sequencing flow cell polished with the polishing solution (Example 6);

FIG. 13 is a sequencing image obtained by sequencing using an unpolished sequencing flow cell;

FIG. 14 is a sequencing image obtained by sequencing using a polished sequencing flow cell; and

FIG. 15 is a sequencing image obtained by sequencing using the sequencing flow cell of Example 8.

### DESCRIPTION OF REFERENCE NUMERALS

1: solid substrate; 10: field of view; 101: detection region; 102: first trackline; 103: second trackline; 105: detection site; 106: intersection point; 107: X-direction first dark point; 108: X-direction first bright point; 109: X-direction second dark point; 110: X-direction second bright point; 111: X-direction third bright point; 112: X-direction fourth bright point; 113: X-direction third dark point; 114: X-direction fifth bright point; 115: X-direction sixth dark point; 116: Y-direction first dark point; 117: Y-direction first bright point; 118: Y-direction second dark point; 119: Y-direction second bright point; 120: Y-direction third bright point; 121: Y-direction third dark point; 122: Y-direction fourth light point; 123: Y-direction fourth dark point; 1011: first detection site; 1012: second detection site; 1013: third detection site; 1014: fourth detection site; 1015: fifth detection site; 1016: sixth detection site; 1017: seventh detection site; 1018: eighth detection site; 1019: ninth detection site; 11, 12: first repeating unit; 13, 14: second repeating unit; 15, 17: symmetry line; 16: axis.

### DETAILED DESCRIPTION

Embodiments of the present application are described in detail below. The embodiments described below are illustrative and are merely used to explain the present application, and they should not be construed as limiting the present application.

The endpoints of the ranges and any values disclosed herein are not limited to the precise ranges or values, and these ranges or values should be understood to encompass values close to these ranges or values. For numerical ranges, the endpoint values of each range, the endpoint values of each range and single point values, as well as single point values, can be combined with each other to obtain one or more new numerical ranges, which should be construed as being specifically disclosed herein.

As used herein, the term “include”, “includes” or “including” is open-ended, i.e., including what is meant by the present application, but not excluding other aspects.

As used herein, the term “optionally” or “optional” generally means that the subsequently described event or condition may, but not necessarily, occur, and this description includes cases where the event or condition occurs, and cases where the event or condition does not occur.

As used herein, the “trackline” is also referred to as a calibration line, recognition line, or trajectory line, and mainly serves to mark the standard FOV and locate the signal position, such that the correspondence between the detection position and the detection signal can be confirmed according to the trackline during the detection process.

As used herein, the term “sequencing” may also be referred to as “nucleic acid sequencing” or “gene sequencing”. The three are used interchangeably and refer to the determination of the type and order of bases in a nucleic acid sequence.

As used herein, the “FOV” refers to the field of view. The application of the solid substrate includes a process of performing multiple cycles of optical imaging (photographing) on a fixed region of the solid substrate by using an optical camera, and the region photographed by the optical camera each time is referred to as a FOV (field of view).

The present application provides a surface treatment method, a polishing solution, a reagent kit, a method for preparing a flow cell, and a flow cell, which are described in detail below, respectively.

### Surface Treatment Method

In one aspect of the present application, the present application provides a surface treatment method. According to the embodiments of the present application, the surface treatment method includes: using a polishing solution to treat a substrate having a first polymer bound to a surface thereof to remove the first polymer from at least a portion of the surface of the substrate, where the polishing solution includes a polishing agent, and the polishing agent is selected from at least one of a second polymer and an inorganic nanomaterial.

During the polishing of the first polymer (soft material) on the substrate, the surface of the substrate may be prone to scratching and corrosion, and abrasive residues remaining after polishing may also persist on the surface of the substrate. In view of this, the inventors have conducted extensive screening and optimization work to obtain a polishing solution suitable for polishing the first polymer. The polishing solution includes one or a combination of a second polymer and an inorganic nanomaterial, and is capable of removing the first polymer from the substrate.

In the present application, the term “substrate” may refer to a solid support. The substrate may include any suitable substrate material, including but not limited to glass, modified glass, functionalized glass, silicon dioxide, quartz, silicon, plastic, metal, metal oxides, or combinations thereof.

In some embodiments, the substrate includes a functional material layer, and the first polymer is formed on the surface of the functional material layer distal to the substrate. In this case, the polishing solution is required to remove the first polymer as completely as possible while avoiding damage to the functional material layer. The expression that the polishing solution of the present application does not damage the substrate described herein may also be understood to mean that the polishing solution does not damage the functional material layer. The “functional material layer” as referred to in the embodiments of the present application denotes a material layer capable of imparting one or more functionalities to the substrate. The specific function exerted by the material layer or the selection of the material layer is not strictly limited in the embodiments of the present application. Illustratively, when the substrate is a sequencing flow cell, the functional material layer may be an organic molecular layer, and the organic molecules bind to both the layer above and the layer below through two kinds of groups of the molecule, thereby serving as a “molecular bridge”. Therefore, the first polymer is immobilized on the surface of the substrate.

According to the embodiments of the present application, a Shore D hardness of the first polymer is denoted as A; a Shore D hardness of the second polymer is denoted as B, and A and B satisfy the relationship: B=A±10 HD. The inventors have found that when the first polymer and the second polymer meet the above hardness relationship, the first polymer can be effectively removed from the substrate without damaging the substrate, and a planar surface can be obtained after polishing.

According to the embodiments of the present application, the first polymer includes a polymer gel. In some embodiments, the first polymer includes a polyacrylamide hydrogel. Illustratively, the first polymer is a polyacrylamide hydrogel.

According to the embodiments of the present application, the second polymer is selected from at least one of polystyrene and polymethylmethacrylate. Therefore, the first polymer can be effectively removed from the substrate without damage or corrosion to the substrate, and abrasive residues can be reduced.

Illustratively, the first polymer is a polyacrylamide hydrogel, and the second polymer is selected from at least one of polystyrene and polymethylmethacrylate. In this case, by polishing the polyacrylamide hydrogel surface using polystyrene and/or polymethylmethacrylate, the polyacrylamide hydrogel can be effectively removed from the surface of the substrate and surface damage of the polished surface is reduced, such that a planar surface is obtained.

According to the embodiments of the present application, the second polymer has a particle size of 100 nm to 1 μm, preferably 200 nm to 800 nm, more preferably 400 nm to 500 nm. Through extensive experimentation, the inventors have determined the above preferable particle size ranges, which allow for effective removal of the first polymer from the substrate without damaging the substrate. In addition, such particle size ranges can avoid breakage of excessively large particles during the polishing process and prevent the broken particles from filling micropores in the target region, which could interfere with normal reactions. It should be understood that, when the surface of the substrate is provided with a microporous structure, and such microporous structure is a structure configured to enable one or more functions of the substrate, the particle size of the second polymer is greater than the pore diameter of the micropores to reduce the risk of the second polymer filling the micropores. Specifically, when the substrate is a sequencing flow cell, the micropores on the surface of the sequencing flow cell serve as sequencing regions. If these micropores are filled, the reactivity of the micropores may be lost, thereby reducing the throughput of the sequencing flow cell. When a large number of micropores in the sequencing region are filled, the number of effective micropores (i.e., micropores capable of participating in sequencing) in the sequencing flow cell is significantly reduced, which further directly impacts the sequencing process and results in failure of the sequencing flow cell. Therefore, the particle size of the second polymer is greater than the pore diameter of the microporous structure in the sequencing flow cell.

According to the embodiments of the present application, based on the total weight of the polishing solution being 100%, the weight percentage content of the second polymer is 0.1% to 10.0%, preferably 0.5% to 5.0%, more preferably 2.0% to 3.0%. Therefore, the first polymer can be effectively removed from the substrate; scratching and corrosion of the substrate are reduced; and abrasive residues are reduced. Illustratively, based on the total weight of the polishing solution being 100%, the weight percentage content of the second polymer may be 0.1%, 0.5%, 0.8%, 1.0%, 1.5%, 1.8%, 2.0%, 2.5%, 2.8%, 3.0%, 3.5%, 4.0%, 4.5%, 5.0%, 5.5%, 6.5%, 7.0%, 7.5%, 8.0%, 8.5%, 9.0%, 9.5%, 10.0%, etc.

In the present application, the term “inorganic nanomaterial” refers to a nanoscale material composed of inorganic substances. Further, through extensive experimental screening, the inventors have found that, compared to other types of inorganic nanomaterials, nanoscale cerium oxide and nanoscale silica, used alone or in combination, can effectively remove the first polymer from the substrate, reduce scratching and corrosion of the substrate, and reduce abrasive residues.

According to the embodiments of the present application, the nanoscale cerium oxide has a particle size selected from 20 nm to 1 μm, preferably 100 nm to 500 nm, more preferably 200 nm to 300 nm; the nanoscale silica has a particle size selected from 20 nm to 200 nm, preferably 30 nm to 150 nm, more preferably 40 nm to 60 nm. Through extensive experimentation, the inventors have determined the above preferable particle size ranges, which allow for effective removal of the first polymer from the substrate without damaging the substrate. In addition, such particle size ranges can avoid breakage of excessively large particles during the polishing process and prevent the broken particles from filling micropores in the target region, which could interfere with normal reactions. Similarly, when the surface of the substrate is provided with a microporous structure, and such microporous structure is a structure configured to enable one or more functions of the substrate, the particle size of the second polymer is greater than the pore diameter of the micropores to reduce the risk of the second polymer filling the micropores. Specifically, when the substrate is a sequencing flow cell, the micropores on the surface of the sequencing flow cell serve as sequencing regions. If these micropores are filled, the reactivity of the micropores may be lost, thereby reducing the throughput of the sequencing flow cell. When a large number of micropores in the sequencing region are filled, the number of effective micropores (i.e., micropores capable of participating in sequencing) in the sequencing flow cell is significantly reduced, which further directly impacts the sequencing process and results in failure of the sequencing flow cell. Therefore, the particle size of the second polymer is greater than the pore diameter of the microporous structure in the sequencing flow cell.

According to the embodiments of the present application, based on the total weight of the polishing solution being 100%, the weight percentage content of the nanoscale cerium oxide is 0.1% to 40.0%, preferably 2.0% to 30.0%, more preferably 5.0% to 10.0%. Illustratively, based on the total weight of the polishing solution being 100%, the weight percentage content of the nanoscale cerium oxide may be 0.1%, 0.5%, 0.8%, 1.0%, 1.5%, 1.8%, 2.0%, 2.5%, 2.8%, 3.0%, 3.5%, 4.0%, 4.5%, 5.0%, 5.5%, 6.5%, 7.0%, 7.5%, 8.0%, 8.5%, 9.0%, 9.5%, 10.0%, 12%, 15%, 18%, 20%, 22%, 25%, 28%, 30%, 32%, 35%, 38%, 40%, etc.

According to the embodiments of the present application, based on the total weight of the polishing solution being 100%, the weight percentage content of the nanoscale silica is 0.1% to 50.0%, preferably 2.0% to 40.0%, more preferably 20.0% to 30.0%. Therefore, the first polymer can be effectively removed from the substrate; scratching and corrosion of the substrate are reduced; and abrasive residues are reduced. Illustratively, based on the total weight of the polishing solution being 100%, the weight percentage content of the nanoscale silica may be 0.1%, 0.5%, 0.8%, 1.0%, 1.5%, 1.8%, 2.0%, 2.5%, 2.8%, 3.0%, 3.5%, 4.0%, 4.5%, 5.0%, 5.5%, 6.5%, 7.0%, 7.5%, 8.0%, 8.5%, 9.0%, 9.5%, 10.0%, 12%, 15%, 18%, 20%, 22%, 25%, 28%, 30%, 32%, 35%, 38%, 40%, 42%, 45%, 48%, 50%, etc.

According to the embodiments of the present application, the polishing solution has a pH selected from 2 to 11, preferably 4 to 10, more preferably 8 to 9. The inventors have found that an appropriate pH can prevent acid- or base-induced corrosion of the substrate during the polishing process, or damage to the surface of the substrate that binds to soft materials, while also enabling more stable removal of the first polymer. Furthermore, through extensive experimentation, the inventors have determined the above preferable pH range for the polishing solution. In some embodiments, the polishing solution further includes: a pH regulator; optionally, the pH regulator is selected from at least one of hydrochloric acid, phosphoric acid, phosphate, aqueous ammonia, sodium hydroxide, carbonate, and Tris.

In one embodiment, the polishing agent is a second polymer, and the pH regulator is one of hydrochloric acid and sodium hydroxide.

In another embodiment, the polishing agent is an inorganic nanomaterial, and the pH regulator is at least one of phosphoric acid, phosphate, aqueous ammonia, carbonate, and Tris. The use of strong acids or strong bases may generate localized areas of high acidity or basicity during application, which may affect the crystalline form and dispersibility of the inorganic nanomaterial (pH shock).

According to the embodiments of the present application, the polishing solution includes a solvent and optionally at least one of the following: a surfactant, a chelating agent, a corrosion inhibitor, and a dispersant.

The surfactant can reduce interfacial tension, allowing the abrasive to act more effectively on the surface to be polished, and enhancing the removal efficiency of the material to be removed from the interface via adsorption or direct friction. The chelating agent can remove metal ions potentially introduced during the polishing process, thereby preventing impurity residues on the surface of the substrate. The corrosion inhibitor can prevent the polishing solution from corroding the substrate. The dispersant provides a stable electrostatic environment for the polishing solution system, allowing the polishing agent to be uniformly dispersed in the solvent and preventing aggregation or sedimentation, which would otherwise cause particle agglomeration and damage the substrate. Typically, when a dispersant is used, the ζ-potential of the polishing solution<−30.

As used herein, the term “ζ-potential” (also referred to as “zeta potential”) refers to the potential at the shear plane, and is an important parameter for evaluating the stability of a system.

According to the embodiments of the present application, the polishing solution is obtained by mixing the respective components. In some embodiments, the method for preparing the polishing solution includes sequentially mixing the second polymer, the corrosion inhibitor, the chelating agent, the surfactant, the pH regulator, a bacteriostatic agent, the dispersant, and the solvent. Therefore, a uniformly mixed solution can be formed.

According to the embodiments of the present application, the surfactant is selected from at least one of sodium dodecyl sulfate, a quaternary ammonium compound, an amino acid-based surfactant, a betaine-based surfactant, polysorbate, a sucrose ester, and Tween; the chelating agent is selected from at least one of ethylenediaminetetraacetate, salicylate, serine and a salt thereof, glycine and a salt thereof, lysine and a salt thereof, oxalate, phthalate, citrate, succinate, tartrate, and malate; the corrosion inhibitor is selected from at least one of 1,2,3-triazole, 1,2,4-triazole, benzotriazole, benzimidazole, and benzothiazole; and the dispersant is selected from at least one of sodium polyacrylate, acetic acid, sodium tripolyphosphate, sodium hexametaphosphate, and a cellulose derivative.

According to the embodiments of the present application, the solvent is selected from water and optionally a polar organic solvent. Illustratively, the solvent is selected from water, or water and an organic solvent. In some preferred embodiments, the polar organic solvent is selected from at least one of ethanol, propylene glycol, N,N-dimethylformamide, and dimethylsulfoxide. Therefore, the materials in the polishing solution can be uniformly mixed to form a uniform system.

According to the embodiments of the present application, based on the total weight of the polishing solution being 100%, the weight percentage content of the surfactant is 0.001% to 1.0%, preferably 0.01% to 0.5%, more preferably 0.05% to 0.1%; the weight percentage content of the chelating agent is 0.01% to 5.0%, preferably 0.1% to 2.0%, more preferably 0.5% to 1.0%; the weight percentage content of the dispersant is 0.01% to 5.0%, preferably 0.1% to 2.0%, more preferably 0.5% to 1.0%; the weight percentage content of the corrosion inhibitor is 0.01% to 5%, preferably 0.1% to 2%, more preferably 0.5% to 1%; and the weight percentage content of the organic solvent is not more than 10%.

Through extensive experimentation, the inventors have determined the above preferable types and concentrations of surfactants, chelating agents, corrosion inhibitors, dispersants, and solvents, such that the first polymer can be effectively removed from the substrate, scratching and corrosion of the substrate are reduced, and abrasive residues are reduced.

According to the embodiments of the present application, the polishing solution further includes a bacteriostatic agent, thereby preventing microbial contamination and prolonging shelf life.

According to the embodiments of the present application, the region of the surface of the substrate to which the first polymer is bound can be divided into a target region and a non-target region. The target region primarily serves to perform specific functions, such as enabling biological or chemical analysis. The presence of soft material in the non-target region results in an indistinct boundary with the target region and interferes with detection in the target region. Therefore, it is necessary to remove the first polymer bound to the surface of the substrate in the non-target region.

In some embodiments, the substrate may be a flow cell or a biochip. According to the embodiments of the present application, at least one surface of the substrate is provided with micropores, and the first polymer is at least bound to the surface of a portion of regions excluding the micropores. For sequencing flow cells, the detection region includes microporous structures, and the first polymer within the micropores can bind to primers to immobilize gene fragments to be analyzed within the micropores for sequencing. However, if the first polymer is further present in regions excluding the micropores, the primers also bind to such first polymer, thereby further immobilizing gene fragments outside the micropores. This results in detection signals appearing outside the micropores, causing significant signal interference and poor quality of the final sequencing data, thereby affecting the accuracy of the sequencing results. Therefore, it is necessary to polish to remove the first polymer present on at least a portion of the surface outside the micropores.

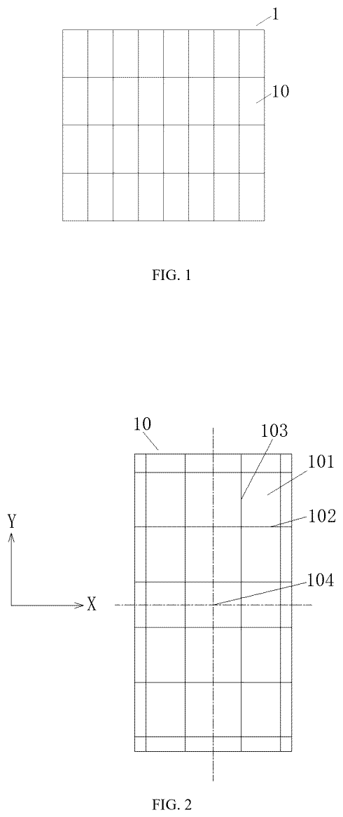

In one embodiment, as shown in FIGS. 1 to 4, the surface of a solid substrate 1 is provided with tracklines, and the tracklines include a plurality of first tracklines 102 arranged in parallel in a first direction and a plurality of second tracklines 103 arranged in parallel in a second direction.

In one embodiment, the first trackline 102 has first repeating units periodically arranged in the first direction, the first repeating unit includes a plurality of sites arranged in the first direction, and the plurality of sites on the first repeating unit are located on the same straight line. That is, all sites on the first trackline 102 are located on the same straight line. Therefore, the identifiability of the sites on the first trackline 102 can be improved, facilitating the recognition of the first trackline 102. In some embodiments, the centers of all sites on each of the first tracklines 102 are aligned along the same straight line in the first direction. In this case, the centers of the optical signals generated at all the sites on the first trackline 102 are also typically on the same straight line, thus further facilitating the recognition of the first trackline 102.

The second trackline 103 has second repeating units periodically arranged in the second direction, the second repeating unit includes a plurality of sites arranged in the second direction, the plurality of sites on the second repeating unit are located on the same straight line. That is, all sites on the second trackline 103 are located on the same straight line. Therefore, the identifiability of the sites on the second trackline 103 can be improved, facilitating the recognition of the second trackline 103. In some embodiments, the centers of all sites on each of the second tracklines 103 are aligned along the same straight line. In this case, the centers of the optical signals generated at all the sites on the second trackline 103 are also typically on the same straight line, thus further facilitating the recognition of the second trackline 103.

In this embodiment, through the surface treatment described above, the first polymer on the surface of the regions excluding the sites within the tracklines can be effectively removed. As a result, the periodically arranged repeating units on the tracklines in both directions exhibit a patterned optical signal characterized by spaced bright and dark regions, facilitating accurate recognition of the tracklines in both directions during optical detection, thereby allowing for FOV calibration and improving detection accuracy.

In this embodiment, the first direction is non-parallel to the second direction. In this case, the first trackline 102 and the second trackline 103 intersect, which is conducive to improving recognizability during optical detection of the solid substrate. In one embodiment, the first direction and the second direction intersect at an included angle of 45° to 135°. Illustratively, the first direction and the second direction are orthogonal to each other, that is, the first trackline 102 and the second trackline 103 are perpendicular to each other. As shown in FIG. 5, the X direction and the Y direction are perpendicular to each other. In this case, the solid substrate is divided into a plurality of rectangular regions by the first trackline 102 and the second trackline 103. It should be understood that a matching algorithm may be developed to allow the first direction and the second direction to intersect at other angles, such as 45°, 60°, 75°, 90°, 105°, 120°, or 135°.

In the embodiments of the present application, the solid substrate is divided into a plurality of FOVs by the tracklines, and the size of the FOV may be adjusted according to the parameters of a corresponding optical system, such as an optical camera. Each FOV is defined as a unit of the solid substrate and includes a first trackline group and a second trackline group. The first trackline group is composed of at least two first tracklines 102, and similarly, the second trackline group is composed of at least two second tracklines 103. Accordingly, the first trackline group and the second trackline group divide the FOV into a plurality of blocks. To improve the recognizability of a standard FOV, in the embodiments of the present application, a plurality of first tracklines 102 in the first trackline group and/or a plurality of second tracklines 103 in the second trackline group are arranged according to a certain rule to enhance the recognizability of the standard FOV.

In some embodiments, the second trackline group includes a plurality of second tracklines 103 that are spaced unevenly. The spacing distance between two second tracklines 103 adjacent to the center of the FOV is greater than the spacing distance between any other two adjacent second tracklines 103. As a result, with the participation of a plurality of first tracklines 102 in the first trackline group, the FOV is divided into a plurality of blocks. Along the first direction, the blocks located in the central region have a larger area than those located in the regions of the two sides. In one embodiment, the spacing distance between two adjacent second tracklines 103 in the second trackline group decreases gradually from the center of the FOV toward both sides along the first direction. Therefore, the area of the blocks gradually decreases from the center of the FOV toward both sides along the first direction. This facilitates identifying the central block, and thereby determining the standard FOV in which the central block is located.

In some embodiments, the first trackline group is composed of a plurality of first tracklines 102 spaced unevenly, and the spacing distance between two first tracklines 102 adjacent to the center of the FOV is the greatest spacing distance. As a result, with the participation of a plurality of second tracklines 103 in the second trackline group, the FOV is divided into a plurality of blocks. Along the second direction, the blocks located in the central region have a larger area than those located in the regions of the two sides. In one embodiment, the spacing distance between two adjacent first tracklines 102 in the first trackline group decreases gradually from the center of the FOV toward both sides along the second direction. Therefore, the area of the blocks gradually decreases from the center of the FOV toward both sides along the second direction. This facilitates identifying the central block, and thereby determining the standard FOV in which the central block is located.

In some embodiments, the second trackline group is composed of a plurality of second tracklines 103 spaced unevenly, and the spacing distance between two second tracklines 103 adjacent to the center of the FOV is the greatest spacing distance; and the first trackline group is composed of a plurality of first tracklines 102 spaced unevenly, and the spacing distance between two first tracklines 102 adjacent to the center of the FOV is the greatest spacing distance. As a result, the FOV is divided into a plurality of blocks, the blocks located in the central region have a larger area than those located in other regions within the FOV, which is conducive to improving the efficiency of identifying the central block. In one embodiment, the spacing distance between two adjacent second tracklines 103 in the second trackline group decreases gradually from the center of the FOV toward both sides along the first direction; and/or the spacing distance between two adjacent first tracklines 102 in the first trackline group decreases gradually from the center of the FOV toward both sides along the second direction. For the resulting FOV, the area of the central block is the largest, and as the distance from the center of the FOV increases, the area of the blocks gradually decreases. In this case, it is not only conducive to rapidly identifying the central block, but also facilitates rapid locating of the boundary of one standard FOV.

It should be understood that the number of the first tracklines 102 in one first trackline group is not strictly limited, and may be a natural number greater than 2. To improve the effective utilization of the solid substrate, that is, to increase the area of the detection region, the number of the first tracklines 102 in the first trackline group does not exceed 10. For example, the number may be 2, 3, 4, 5, 6, 7, 8, 9, or 10. In some embodiments, the number of the first tracklines 102 in one first trackline group is even, such that one FOV is divided into an odd number of segments in the second direction. In this case, only one central block exists and is located at the very center of the FOV, thereby facilitating identification of the central block. Similarly, the number of the second tracklines 103 in the second trackline group is not strictly limited, and may be a natural number greater than 2. To improve the effective utilization of the solid substrate, that is, to increase the area of the detection region, the number of the second tracklines 103 in the second trackline group does not exceed 10. For example, the number may be 2, 3, 4, 5, 6, 7, 8, 9, or 10. In some embodiments, the number of the second tracklines 103 in one second trackline group is even, such that one FOV is divided into an odd number of segments in the first direction. In this case, only one central block exists and is located at the very center of the FOV, thereby facilitating the identification of the central block.

FIG. 2 illustrates one example of a 6×4 trackline in a standard FOV. Specifically, the standard FOV 10 has a plurality of blocks, each corresponding to one detection region 101, which are defined by 6 first tracklines 102 in the first direction and 4 second tracklines 103 in the second direction. The spacing distance between two second tracklines 103 at the center in the second direction is greater than the spacing distance between any other two adjacent second tracklines 103, such that the central block has the largest area and is more easily recognizable. Since the number of both the first tracklines 102 and the second tracklines 103 is even, the number of blocks formed by dividing the standard FOV in either the first direction or the second direction is odd, thereby further facilitating the locating of the central block (i.e., the block where 104 is located), and thus facilitating the identification of the boundaries of the standard FOV.

In one embodiment, the first repeating unit includes at least one set of long-period sites, the long-period sites include at least three first sites, and a first distance between any two adjacent first sites is equal. The arrangement of the long-period sites in the first repeating unit enables the generation of continuous periodic optical signals during optical imaging, thereby facilitating accurate recognition of the first trackline 102 by software. In the embodiments of the present application, the sites on the same first trackline 102 are aligned along the same straight line, and the distance between sites may refer to the length of the line connecting the centers of two sites, or the shortest line connecting the outer edges of two sites. It should be understood that the standard for determining the distance in the same trackline 102 is consistent. Illustratively, when the sites are in the form of a circle (such as micropore sites in a biochip), the distance between sites refers to the length of the line connecting the respective centers of the two sites.

In one embodiment, the first repeating unit further includes a second site disposed on a first side of the long-period sites, and a second distance between a first site adjacent to the second site in the long-period sites and the second site is greater than the first distance. Therefore, a region containing no sites is formed between the long-period sites and the second site, and this region is presented as a dark region in an optical image acquired by optical detection.

In one embodiment, the second distance≥the first distance×2. In this case, the difference in brightness between the long-period sites and the second site can be enhanced, facilitating the recognition of the first trackline 102. Illustratively, the second distance=the first distance×2.

In one embodiment, the first repeating unit includes a second site disposed on a first side and a third site disposed on a second side of the long-period sites. A second distance between a first site adjacent to the second site in the long-period sites and the second site is greater than the first distance, and a third distance between a first site adjacent to the third site in the long-period sites and the third site is greater than the first distance. It should be understood that the first side and the second side are based on the opposite sides of a reference object. For example, when the first repeating unit is located on the transverse axis, the first side of the long-period sites refers to the left side (or the right side) of the long-period sites, and on the contrary, the second side of the long-period sites refers to the right side (or the left side) of the long-period sites. Therefore, regions containing no sites are formed between the long-period sites and the second site and between the long-period sites and the third site, and the regions are presented as dark regions in an optical image acquired by optical detection, such that a bright (second site)-dark-bright (long-period site)-dark-bright (third site) strip is formed, the arrangement of spaced dark and bright regions in the first direction exhibits higher regularity, and the recognizability of the first trackline 102 is improved. In one embodiment, when the third distance≥the first distance×2, the difference in brightness between the long-period sites and the third site can be enhanced, which is conducive to improving the recognition accuracy for the central block in the FOV 10. Illustratively, the third distance=the first distance×2.

In the embodiments of the present application, the second distance and the third distance may be identical or different. In one embodiment, the second distance is equal to the third distance. Therefore, the second site, the long-period sites, and the third site are arranged symmetrically, forming a symmetric bright (second site)-dark-bright (long-period site)-dark-bright (third site) strip, which exhibits enhanced recognizability, thereby improving the recognizability of the first trackline 102.

In one embodiment, the first repeating unit includes one set of long-period sites and a second site disposed on a first side of the long-period sites, and the distance between the next site in the extension direction of the second site and the second site is greater than the first distance. In this case, a region containing no sites is formed on both sides of the second site, such that a dark-(second site)-dark-bright (long-period site) strip is present on the first side of the long-period sites. The next site in the extension direction of the second site may be a site in the same first repeating unit where the second site is located, or may be a site in another adjacent first repeating unit. When the next site in the extension direction of the second site is a site in another adjacent first repeating unit, the first side of the long-period sites in the first repeating unit is provided with the second site, and a dark region is arranged in the extension direction of the second site. In this case, the first side of the first repeating unit does not contain other sites. Illustratively, the distance between the next site in the extension direction of the second site and the second site=the first distance×3. That is, a dark region with a length of the first distance is arranged in the extension direction of the second site.

As shown in FIG. 5, on one trackline, the apertured sites are indicated by solid circles. In this case, in an optical image acquired by optically imaging the solid substrate, the regions corresponding to the solid circles are present as bright regions, and the regions between the solid circles are presented as dark regions in the optical image. At an intersection point 106 of the tracklines in the two directions, in the X direction, the first repeating unit starts at the intersection point 106 and no site is provided at the end of the first repeating unit, i.e., with an X-direction first dark point 107. As a result, in adjacent first repeating units, at least one dark point is present between an X-direction first bright point 108 at the end of a first repeating unit 11 and an X-direction first bright point 108 in the second repeating unit 12, such that the first trackline 102 in the first direction can be accurately recognized.

In another embodiment, the first repeating unit includes one set of long-period sites, a second site disposed on a first side of the long-period sites, and a third site disposed on a second side of the long-period sites, and the second distance=the third distance=the first distance×2, thereby enhancing the symmetry of the first repeating unit, improving the recognizability of the first trackline 102, simplifying algorithm calculation methods, and enhancing data processing capability. In one embodiment, the distance between the next site in the extension direction of the second site and the second site is greater than the first distance, and the distance between the next site in the extension direction of the third site and the third site is greater than the first distance. The next site in the extension direction of the second site may be a site in the same first repeating unit where the second site is located, or may be a site in another adjacent first repeating unit; similarly, the next site in the extension direction of the third site may be a site in the same first repeating unit where the third site is located, or may be a site in another adjacent first repeating unit. When the next site in the extension direction of the second site is a site in an adjacent first repeating unit, and the next site in the extension direction of the third site is a site in another adjacent first repeating unit, the first repeating unit is composed of the second site, the long-period sites, and the third site, and forms the arrangement of the second site, the long-period sites, and the third site, and a dark region is arranged in each of the extension directions of the second site and the third site. Illustratively, in adjacent first repeating units, the distance between the adjacent second site and third site=the first distance×3. That is, a dark region with a length of the first distance is arranged in each of the extension directions of the second site and the third site.

As shown in FIG. 5, in an optical image acquired by optically imaging the solid substrate, both ends of the first repeating unit 11 outlined by the dashed box are dark points, such that the two dark points of two adjacent first repeating units are contiguous, thereby effectively improving recognizability of the bright points on the first trackline 102. The dashed lines shown in the figure are not physically present on the flow cell.

In one implementation, the first repeating unit has a fourth site disposed in the extension direction of the second site; in one embodiment, the first repeating unit has a fifth site disposed in the extension direction of the third site. In one embodiment, the first repeating unit has a fourth site disposed in the extension direction of the second site, and the first repeating unit has a fifth site disposed in the extension direction of the third site. As shown in FIG. 5, in the optical image acquired by optically imaging the solid substrate, the long-period sites in the first repeating unit 11 correspond to an X-direction second bright point 110, an X-direction third bright point 111, and an X-direction fourth bright point 112. On the right side of the long-period sites, an X-direction third dark point 113, an X-direction fifth bright point 114, and an X-direction sixth dark point 115 are sequentially arranged, thereby making the long-period sites more easily recognizable.

In one embodiment, the first repeating unit includes a fourth site located at the end of the first side and a fifth site located at the end of the second side, the fourth site serves as the end site of the first repeating unit on the first side, and the fifth site serves as the end site of the first repeating unit on the second side. That is, the first repeating unit is composed of the long-period sites, the second site, the third site, the fourth site, and the fifth site, and forms the arrangement of the fourth site, the second site, the long-period sites, the third site, and the fifth site. Dark regions are arranged on both sides of the second site, the long-period sites, and the third site. Accordingly, in the optical image, the first repeating unit is presented as a bright (fourth site)-dark-bright (second site)-dark-long-period bright (long-period site)-dark-bright (third site)-dark-bright (fifth site) strip, such that the arrangement of spaced dark and bright regions in the first direction exhibits higher regularity, and the recognizability of the first trackline 102 is improved.

As shown in FIG. 5, in the optical image acquired by optically imaging the solid substrate, the long-period sites in the first repeating unit 11 correspond to an X-direction second bright point 110, an X-direction third bright point 111, and an X-direction fourth bright point 112; on the right side of the long-period sites, an X-direction third dark point 113, an X-direction fifth bright point 114, and an X-direction sixth dark point 115 are sequentially arranged; on the left side of the long-period sites, an X-direction second dark point 109, an X-direction first bright point 108, and an X-direction first dark point 107 are sequentially arranged, thereby further improving the recognizability of the long-period sites.

In some embodiments of this implementation, the second distance is greater than the first distance, such that a dark region is present between the long-period sites and the second site during optical imaging. In one embodiment, when the second distance≥the first distance×2, the difference in brightness between the long-period sites and the second site can be enhanced, which is conducive to improving the recognition accuracy for the central block in the FOV 10. Illustratively, the second distance=the first distance×2.

In some embodiments of this implementation, the third distance is greater than the first distance. In one embodiment, when the third distance≥the first distance×2, the difference in brightness between the long-period sites and the third site can be enhanced, which is conducive to improving the recognition accuracy for the central block in the FOV 10. Illustratively, the third distance=the first distance×2.

In some embodiments of this implementation, the second distance=the third distance, thereby enhancing the symmetry of the first repeating unit, improving the recognizability of the first trackline 102, simplifying algorithm calculation methods, and enhancing data processing capability.

In some embodiments of this implementation, in two adjacent first repeating units, a fourth distance between the adjacent fourth site and the fifth site is greater than or equal to the first distance. In some embodiments, in two adjacent first repeating units, no site is provided between the adjacent fourth site and the fifth site. In this case, the end of at least one side of the first repeating unit includes a vacant region where no site is provided, which is presented as a dark region in the optical image acquired by optical imaging.

In one embodiment, the fourth distance≥the first distance×2. In this case, the side of the first repeating unit where the end is a dark region becomes relatively prominent, thereby facilitating recognition. In one embodiment, the fourth distance=the first distance×2. In this case, one scenario exists where: in two adjacent first repeating units, one side of the first first repeating unit terminates with a vacant region occupying the position of one site, while the side of the second first repeating unit adjacent to the first first repeating unit terminates with a site. It can also be interpreted as: the end of one side of a first repeating unit includes a vacant region where no site is provided, whereas the end of the other side is provided with a site. In this case, in the optical image, the first repeating unit is presented as a dark-bright (fourth site)-dark-bright (second site)-dark-long-period bright (long-period site)-dark-bright (third site)-dark-bright (fifth site) strip in the optical image, or as a bright (fourth site)-dark-bright (second site)-dark-long-period bright (long-period site)-dark-bright (third site)-dark-bright (fifth site)-dark strip.

In another embodiment, the fourth distance=the first distance×3. In this case, each of the ends of both sides of the first repeating unit includes a vacant region where no site is provided. That is, both ends of the first repeating unit appear as dark regions in the optical image acquired by optical imaging. Accordingly, in the optical image, the first repeating unit is presented as a dark-bright (fourth site)-dark-bright (second site)-dark-long-period bright (long-period sites)-dark-bright (third site)-dark-bright (fifth site)-dark strip, such that the arrangement of spaced dark and bright regions in the first direction exhibits high regularity, and the recognizability of the first trackline 102 is improved. Furthermore, since the end of each first repeating unit includes a vacant region where no site is provided, a longer dark region is formed between adjacent first repeating units in the image acquired by optical imaging, which facilitates the recognition of the first repeating unit.

In some embodiments, the fourth site is identical to the second site, and the fifth site is identical to the third site. That is, the fourth site and the second site are the same site, and the fifth site and the third site are the same site. In this case, the first repeating unit may be presented in the optical image as a dark-bright (second site or fourth site)-dark-long-period bright (long-period site)-dark-bright (third site or fifth site) strip, or as a dark-bright (second site or fourth site)-dark-long-period bright (long-period site)-dark-bright (third site or fifth site)-dark strip, or as a bright (second site or fourth site)-dark-long-period bright (long-period site)-dark-bright (third site or fifth site) strip.

In one embodiment, each first repeating unit of the first trackline 102 in the first direction includes one set of long-period sites, that is, one set of long-period sites is composed of three first sites. As shown in FIG. 5, in the optical image acquired by optical imaging, in the X direction, the first repeating unit 11 includes one set of long-period sites consisting of the X-direction second bright point 110, the X-direction third bright point 111, and the X-direction fourth bright point 112. The presence of three consecutive bright points can effectively improve the recognizability of the first trackline 102.

In one embodiment, the first repeating unit includes one set of long-period sites, and the long-period sites include three first sites, a second site and a fourth site sequentially arranged on the first side of the long-period sites, and a third site and a fifth site arranged on the second side of the long-period sites. The first distance between any two adjacent first sites is equal. The second distance between a first site adjacent to the second site in the long-period sites and the second site=the third distance between a first site adjacent to the third site in the long-period sites and the second site=the first distance×2. In two adjacent first repeating units, the fourth distance between the adjacent fourth site and the fifth site=the first distance×3. As shown in FIG. 5, in the optical image acquired by optical imaging, the first repeating units are periodically arranged in the X direction starting from the intersection point 106. Specifically, the first repeating unit 11 includes an X-direction first dark point 107, an X-direction first bright point 108, an X-direction second dark point 109, an X-direction second bright point 110, an X-direction third bright point 111, an X-direction fourth bright point 112, an X-direction third dark point 113, an X-direction fifth bright point 114, and an X-direction sixth dark point 115. The X-direction third bright point 111 serves as the center of symmetry of the repeating unit. This regular periodic arrangement effectively improves the recognizability of the first trackline 102 in the first direction. The first repeating unit 11 is adjacent to a second repeating unit 12, such that two X-direction first bright points 108 are spaced apart by two X-direction first dark points 107, thereby improving the recognizability of single bright points.

As one implementation of the above embodiment, the sites on the first trackline 102 are in the form of a symmetrical pattern. In some embodiments, the sites on the first trackline 102 are in the form of a circle or a regular polygon. Illustratively, the regular polygon may be an equilateral triangle, a rhombus, a square, a regular pentagon, a regular hexagon, or a regular octagon.

In the embodiments of the present application, a plurality of tracklines are also arranged in parallel in the second direction, i.e., second tracklines 103. In one embodiment, each of the second tracklines 103 includes a plurality of sites arranged in the second direction, and the plurality of sites on the second repeating unit are located on the same straight line. In one embodiment, the second trackline 103 includes second repeating units periodically and cyclically arranged, and the second repeating unit and the first repeating unit are identical or different.

In one embodiment, each second repeating unit of the second trackline 103 includes at least one set of short-period sites, the short-period sites consist of one or two sixth sites, and a fifth distance between any two adjacent sixth sites is equal. The short-period sites are provided in the second repeating unit to distinguish them from the first repeating units, which facilitates the determination of the relative orientation of the FOV 10. In one embodiment, as shown in FIG. 5, a second repeating unit 13 outlined by the dashed box includes a Y-direction second bright point 119 and a Y-direction third bright point 120, such that the second trackline 103 in the second direction can be effectively recognized. In the embodiments of the present application, the sites on the same second trackline 103 are aligned along the same straight line, and the distance between sites may refer to the length of the line connecting the centers of two sites, or the shortest line connecting the outer edges of two sites. It should be understood that the standard for determining the distance in the same trackline is consistent. Illustratively, when the sites are in the form of a circle (such as micropore sites in a biochip), the distance between sites refers to the length of the line connecting the respective centers of the two sites.

In one embodiment, the second repeating unit further includes a seventh site disposed on a first side of the short-period sites, and a sixth distance between a sixth site adjacent to the seventh site and the seventh site in the short-period sites is greater than the fifth distance. Therefore, a region containing no sites is formed between the short-period sites and the sixth site, and this region is presented as a dark region in an image acquired by optical detection.

In one embodiment, the sixth distance≥the fifth distance×2. In this case, the difference in brightness between the short-period sites and the seventh site can be enhanced, facilitating the recognition of the second trackline 103 of the FOV 10. Illustratively, the sixth distance=the fifth distance×2. As shown in FIG. 5, in the optical image acquired by optical imaging, in the second repeating unit 13, the Y-direction second bright point 119 and the Y-direction third bright point 120 correspond to the short-period sites. A Y-direction third dark point 121 is provided on one side of the short-period sites, such that the short-period sites can be effectively recognized.

In one embodiment, the second repeating unit includes a seventh site disposed on a first side of the short-period sites, and an eighth site disposed on a second side of the short-period sites, a sixth distance between a sixth site adjacent to the seventh site in the short-period sites and the seventh site is greater than the fifth distance, and a seventh distance between a sixth site adjacent to the eighth site in the short-period sites and the eighth site is greater than the fifth distance. It should be understood that the first side and the second side are based on the opposite sides of a reference object. For example, when the second repeating unit is located on the longitudinal axis, the first side of the short-period sites refers to the upper side of the short-period sites, and on the contrary, the second side of the short-period sites refers to the lower side of the short-period sites. Therefore, regions containing no sites are formed between the short-period sites and the seventh site and between the short-period sites and the eighth site, and the regions are presented as dark regions in an optical image acquired by optical detection, such that a bright (sixth site)-dark-bright (short-period site)-dark-bright (seventh site) strip is formed, the arrangement of spaced dark and bright regions in the second direction exhibits higher regularity, and the recognizability of the second trackline 103 is improved. In one embodiment, when the seventh distance≥the fifth distance×2, the difference in brightness between the short-period sites and the seventh site can be enhanced, which is conducive to improving the recognition accuracy for the central block in the FOV 10. Illustratively, the seventh distance=the fifth distance×2.

In the embodiments of the present application, the sixth distance and the seventh distance may be identical or different. In one embodiment, the sixth distance is equal to the seventh distance. Therefore, the sixth site, the long-period sites, and the seventh site are symmetrically arranged, which is conducive to improving the recognizability of the second trackline 103.

In one embodiment, the second repeating unit includes one set of short-period sites and a seventh site disposed on a first side of the short-period sites, and the distance between the next site in the extension direction of the seventh site and the seventh site is greater than the fifth distance. In this case, a region containing no sites is formed on both sides of the seventh site, such that a dark (seventh site)-dark-bright (short-period site) strip is present on the first side of the short-period sites. The next site in the extension direction of the seventh site may be a site in the same second repeating unit where the seventh site is located, or may be a site in another adjacent second repeating unit. When the next site in the extension direction of the seventh site is a site in another adjacent second repeating unit, the first side of the short-period sites in the second repeating unit is provided with the seventh site, and a dark region is arranged in the extension direction of the seventh site. In this case, the first side of the second repeating unit does not contain other sites. Illustratively, the distance between the next site in the extension direction of the seventh site and the seventh site=the first distance×3. That is, a dark region with a length of the first distance is arranged in the extension direction of the sixth site.

As shown in FIG. 5, in the image acquired by optical imaging, in the second repeating unit 13, the Y-direction second bright point 119 and the Y-direction third bright point 120 correspond to the short-period sites. A Y-direction third dark point 121 is provided on one side of the short-period sites, and a Y-direction second dark point 118 is provided on the other side, thereby further improving the recognizability of the short-period sites.

In another embodiment, the second repeating unit includes one set of short-period sites, a seventh site disposed on the first side of the short-period sites, and an eighth site disposed on the second side of the short-period sites, and the sixth distance=the seventh distance=the fifth distance×2. Therefore, the symmetry of the second repeating unit is enhanced, the recognizability of the second trackline 103 is improved, the algorithm calculation methods are simplified, and the data processing capability is enhanced. In one embodiment, the distance between the next site in the extension direction of the seventh site and the seventh site is greater than the fifth distance, and the distance between the next site in the extension direction of the eighth site and the eighth site is greater than the fifth distance. The next site in the extension direction of the seventh site may be a site in the same second repeating unit where the seventh site is located, or may be a site in another adjacent second repeating unit; similarly, the next site in the extension direction of the eighth site may be a site in the same second repeating unit where the eighth detection site is located, or may be a site in another adjacent second repeating unit. When the next site in the extension direction of the seventh site is a site in an adjacent second repeating unit, and the next site in the extension direction of the eighth site is a site in another adjacent second repeating unit, the second repeating unit is composed of the seventh site, the short-period sites, and the eighth site, and forms the arrangement of the seventh site, the short-period sites, and the eighth site, and a dark region is arranged in each of the extension directions of the seventh site and the eighth site. Illustratively, in adjacent second repeating units, the distance between the adjacent seventh site and the eighth site=the fifth distance×3. That is, a dark region with a length of the first distance is arranged in each of the extension directions of the seventh site and the eighth site.

As shown in FIG. 5, in the optical image acquired by optical imaging, in the second repeating unit 13, the Y-direction second bright point 119 and the Y-direction third bright point 120 correspond to the short-period sites. A Y-direction third dark point 121, a Y-direction fourth bright point 122, and a Y-direction fourth dark point 123 are sequentially arranged on one side of the short-period sites, such that the double bright points and the single bright point are separated by single dark points, thereby improving the recognizability of the double bright points and single bright points.

In some embodiments of this implementation, the sixth distance is greater than the fifth distance, such that a dark region is present between the short-period sites and the seventh site during optical imaging. In one embodiment, when the sixth distance≥the fifth distance×2, the difference in brightness between the short-period sites and the seventh site can be enhanced, which is conducive to improving the recognition accuracy for the central block in the FOV 10. Illustratively, the sixth distance=the fifth distance×2.

In some embodiments of this implementation, the seventh distance is greater than the fifth distance. In one embodiment, when the seventh distance≥the fifth distance×2, the difference in brightness between the short-period sites and the eighth site can be enhanced, which is conducive to improving the recognition accuracy for the central block in the FOV 10. Illustratively, the seventh distance=the fifth distance×2.

In some embodiments of this implementation, the sixth distance=the seventh distance, thereby enhancing the symmetry of the second repeating unit, improving the recognizability of the second trackline 103, simplifying algorithm calculation methods, and enhancing data processing capability.

In some embodiments of this implementation, in adjacent second repeating units, the distance between the adjacent sixth site and the seventh site is greater than the sixth distance. In some embodiments, in two adjacent second repeating units, no site is provided between the adjacent seventh site and the eighth site. In this case, the end of at least one side of the second repeating unit includes a vacant region where no site is provided, which is presented as a dark region in the image acquired by optical imaging.

In one embodiment, in adjacent second repeating units, the distance between the adjacent sixth site and the seventh site≥the sixth distance×2. In this case, one scenario exists where: in two adjacent second repeating units, one side of the first second repeating unit terminates with a vacant region occupying the position of one site, while the side of the second second repeating unit adjacent to the first second repeating unit terminates with a site. It can also be interpreted as: the end of one side of a second repeating unit includes a vacant region where no site is provided, whereas the end of the other side is provided with a site. In this case, the second repeating unit is presented in the optical image as a dark-bright (seventh site)-dark-short-period bright (short-period site)-dark-bright (eighth site) strip, or as a bright (seventh site)-dark-short-period bright (short-period site)-dark-bright (eighth site)-dark strip.

In one embodiment, in adjacent second repeating units, the distance between the adjacent sixth site and the seventh site=the fifth distance×3. In this case, each of the ends of both sides of the second repeating unit includes a vacant region where no site is provided. That is, both ends of the second repeating unit appear as dark regions in the optical image acquired by optical imaging. Accordingly, in the optical image, the second repeating unit is presented as a dark-bright (seventh site)-dark-short-period bright (short-period site)-dark-bright (eighth site)-dark strip, such that the arrangement of spaced dark and bright regions in the second direction exhibits high regularity, and the recognizability of the second trackline 103 is improved. Furthermore, since the end of each second repeating unit includes a vacant region where no site is provided, a longer dark region is formed between adjacent second repeating units in the image acquired by optical imaging, which facilitates the recognition of the second repeating unit.

As shown in FIG. 5, in the image acquired by optical imaging, in the second repeating unit 13, the Y-direction second bright point 119 and the Y-direction third bright point 120 correspond to the short-period sites. A Y-direction third dark point 121, a Y-direction fourth bright point 122, and a Y-direction fourth dark point 123 are sequentially arranged on one side of the short-period sites, and a Y-direction second dark point 118, a Y-direction second bright point 117, and a Y-direction first dark point 116 are sequentially arranged on the other side, such that the single bright points on both sides of the double bright points are separated by single dark points, exhibiting a regular distribution, thereby improving the recognizability of the second trackline 103 in the second direction.

In one embodiment, the second repeating unit includes one set of short-period sites, and the short-period sites include two sixth sites, a seventh site disposed on the first side of the short-period sites, and an eighth site disposed on the second side of the short-period sites. The fifth distance between any two adjacent sixth sites is equal. The sixth distance between a sixth site adjacent to the seventh site in the short-period sites and the seventh site=the seventh distance between a sixth site adjacent to the eighth site in the short-period sites and the eighth site=the fifth distance×2. In two adjacent second repeating units, the eighth distance between the adjacent seventh site and the eighth site=the fifth distance×3. As shown in FIG. 5, in the image acquired by optical imaging, the second repeating units are periodically arranged in the Y direction. Specifically, the second repeating unit 13 includes a Y-direction first dark point 116, a Y-direction first bright point 117, a Y-direction second dark point 118, a Y-direction second bright point 119, a Y-direction third bright point 120, a Y-direction third dark point 121, a Y-direction fourth bright point 122, a Y-direction fourth dark point 123. The midpoint between the Y-direction second bright point 119 and the Y-direction third bright point 120 serves as the center of symmetry of the repeating unit. This regular periodic arrangement effectively improves the recognizability of the second trackline 103 in the second direction. The second repeating unit 13 is adjacent to a second repeating unit 14, such that two Y-direction first bright points 117 are spaced apart by two Y-direction first dark points 116, thereby improving the recognizability of single bright points.

As shown in FIG. 5, in the X direction, two sides of the intersection point 106 are each provided with one dark point, and in the Y direction, two sides of the intersection point 106 are also each provided with one dark point, such that the recognizability of the intersection point is effectively improved.

As one implementation of the above embodiment, the sites on the second trackline 103 are in the form of a symmetrical pattern. In some embodiments, the sites on the second trackline 103 are in the form of a circle or a regular polygon. Illustratively, the regular polygon may be an equilateral triangle, a rhombus, a square, a regular pentagon, a regular hexagon, or a regular octagon.

In one embodiment, the surface of the solid substrate is provided with a plurality of detection regions, and the first tracklines 102 and the second tracklines 103 are arranged to intersect among the detection regions. That is, the tracklines serve to divide the solid substrate into a plurality of sequencing regions. Similarly, when measured in FOV units, a first trackline group and a second trackline group divide the FOV into a plurality of blocks.

In one embodiment, the intersection point of the first trackline 102 and the second trackline 103 is a center of symmetry of two adjacent repeating units in either direction. As shown in FIG. 5, in the X direction, the intersection point 106 serves as the center of symmetry of the first repeating unit 11 and the first repeating unit 12; in the Y direction, the intersection point 106 serves as the center of symmetry of the second repeating unit 13 and the second repeating unit 14. Any intersection point between the X direction and Y direction serves as the center of symmetry of two adjacent repeating units in either direction. This arrangement mode ensures regular arrangement of repeating units between adjacent intersection points, thereby improving the recognizability of tracklines in both directions.

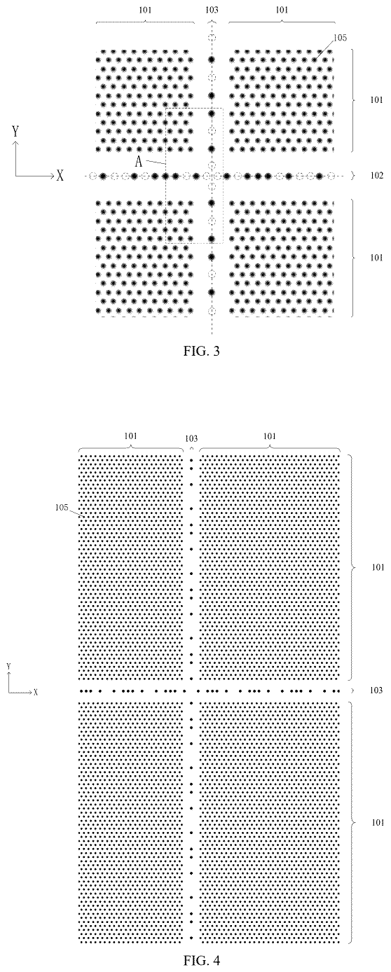

In one embodiment, as shown in FIGS. 3 and 4, the detection region has detection sites arranged in an array. Illustratively, pores are formed in the detection region to create a pore structure, and test samples are immobilized within the pore structure. In this case, each pore corresponds to one detection site.

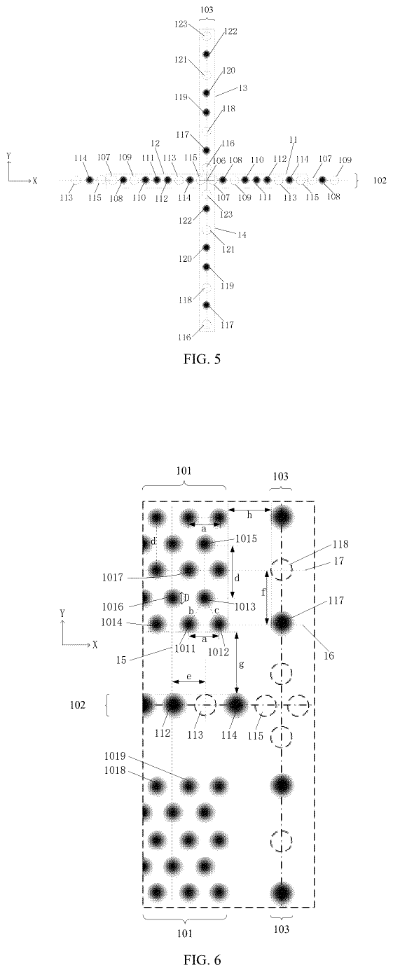

In one embodiment, the spacing distance a between any two adjacent detection sites in the first direction is equal. As shown in FIG. 6, in a detection region 101 in the X direction, a first detection site 1011 is adjacent to a second detection site 1012 with a spacing distance of a, and the first detection site 1011 is also adjacent to a fourth detection site 1014 with a spacing distance of a. The term spacing distance herein refers to the linear distance between geometric centers of two adjacent detection sites. If the detection site is in the form of a circular, the spacing distance is the linear distance between the circle centers of two adjacent detection sites, i.e., the straight-line length connecting two circle centers.

In one embodiment, as shown in FIG. 6, in the detection region 101, the spacing distance d between any two adjacent detection sites in the second direction is equal.

In one embodiment, as shown in FIG. 6, the pattern formed by the first detection site 1011, the second detection site 1012, and a third detection site 1013 constitutes an equilateral triangle with equal side lengths a, b, and c. In the Y direction, the spacing distance d between the adjacent third detection site 1013 and a fifth detection site 1015 satisfies d=\sqrt{3}a. This arrangement ensures that distances between different detection sites meet optical resolution spacing requirements, allowing optical detection to resolve signals between two adjacent detection sites.

In one embodiment, in any one row of the detection sites in the first direction, the symmetry line between two adjacent detection sites in the second direction passes through the center of a detection site in an adjacent row. As shown in FIG. 6, in the X direction, the adjacent first detection site 1011 and fourth detection site 1014 are symmetric about a symmetry line 15. In a row adjacent to the row containing the first detection site 1011 in the X direction, a sixth detection site 1016 is provided, and the symmetry line 15 passes through the center of this detection site. In some embodiments, the detection sites exhibit regular shapes such as circular sites, and the symmetry line 15 passes through the geometric center (i.e., circle center) of such circular sites.

In one embodiment, similarly, in any one column of the detection sites in the second direction, the symmetry line between two adjacent detection sites in the first direction passes through the center of a detection site in an adjacent column. As shown in FIG. 6, in the Y direction, the adjacent third detection site 1013 and fifth detection site 1015 are symmetric about a symmetry line 17. In a column adjacent to the column containing the third detection site 1013 in the Y direction, a seventh detection site 1017 is provided, and the symmetry line 17 passes through the center of this detection site. In some embodiments, the detection sites exhibit regular shapes such as circular sites, and the symmetry line 17 passes through the geometric center (i.e., circle center) of such circular sites.

In one embodiment, the central symmetry axis in the first direction of any one site on the second trackline 103 passes through the center of a detection site in an adjacent detection region, or: the central symmetry axis in the first direction of any one site on the second trackline 103 coincides with the symmetry line between two adjacent detection sites in any odd-numbered or even-numbered rows from the site in a detection region. As shown in FIG. 6, in the X direction, an axis 16 (i.e., central symmetry axis) of the Y-direction first bright point 117 on the second trackline 103 passes through the geometric centers of the first detection site 1011, the second detection site 1012, and other detection sites located on the same straight line with the first detection site 1011 and the second detection site 1012 in an adjacent detection region 101.

In one embodiment, the central symmetry axis in the second direction of any one site on the first trackline 102 coincides with the symmetry line between two adjacent detection sites in any odd-numbered or even-numbered rows from the site in a detection region. As shown in FIG. 6, in the Y direction, the symmetry line 15 (i.e., central symmetry axis) of the X-direction fourth bright point 112 on the first trackline 102 coincides with the symmetry line between the first detection site 1011 and the fourth detection site 1014 in the first row from the site in the above detection region 101, and also coincides with the symmetry lines of corresponding two adjacent sites in other odd-numbered rows, e.g., the 3rd, 5th, 7th rows. For another example, the symmetry line 15 (i.e., central symmetry axis) of the X-direction fourth bright point 112 on the first trackline 102 coincides with the symmetry line between an eighth detection site 1018 and a ninth detection site 1019 in the first row from the site in the below detection region 101.

In one embodiment, in the first direction, the first spacing distance on the first trackline 102 equals twice the spacing distance between adjacent detection sites in the detection region in the first direction. As shown in FIG. 6, in the X direction, on first trackline 102, the first spacing distance between the X-direction second dark point 109 and the X-direction second bright point 110 is e, and the spacing distance between the first detection site 1011 and the second detection site 1012 in the detection region 101 in the X direction is a, where the spacing distance e may be equal to the spacing distance a.

In one embodiment, the spacing distance between adjacent detection sites on the second trackline 103 in the second direction is equal to the spacing distance between adjacent detection sites in the detection region in the second direction. As shown in FIG. 6, in the Y direction, on the second trackline 103, the spacing distance between the Y-direction first bright point 117 and the Y-direction second dark point 118 is d. In the detection region 101, in the Y direction, the spacing distance between the third detection site 1013 and the fifth detection site 1015 is d, and the spacing distance d may be equal to the spacing distance f, thereby facilitating algorithm calculation.

In one embodiment, the maximum diameter of sites on the tracklines exceeds that of detection sites in the detection regions, such that the tracklines are more easily recognized. The maximum diameter is the linear distance between two points that are farthest from each other in the site. For a circular site, the diameter is the diameter of the circle.

In one embodiment, the maximum diameter on the trackline is 400 to 500 nm, including but not limited to, 400 nm, 410 nm, 420 nm, 430 nm, 440 nm, 450 nm, 460 nm, 470 nm, 480 nm, 490 nm, 500 nm, etc. The maximum diameter of the sites on the first trackline 102 may be identical to or different from the maximum diameter of the sites on the second trackline 103.

In one embodiment, the maximum diameter of the sites on the first trackline 102 is identical to the maximum diameter of the sites on the second trackline 103. Illustratively, the maximum diameter of all sites in the first and second directions is 450 nm.

In one embodiment, as shown in FIG. 6, the perpendicular distance g between a boundary line between the detection region and the trackline and the central symmetry axis of the first trackline 102 satisfies g≥n×D, D is the diameter of the pore site in the detection region, and n is a non-zero natural number. In one embodiment, n≥3. In one embodiment, n is 4 to 6, and specifically may by 4, 5, or 6, thereby widening the dark region between the first trackline 102 and the boundary of the detection region 101 to enhance the recognizability of the first trackline 102.

In one embodiment, as shown in FIG. 6, the perpendicular distance h between a boundary line between the detection region and the trackline and the central symmetry axis of the second trackline 103 satisfies h≥m×D, D is the diameter of the pore site in the detection region, and m is a non-zero natural number. In one embodiment, m≥5. In one embodiment, m is 6 to 8, and specifically may be 6, 7, or 8, thereby widening the dark region between the second trackline 103 and the boundary of the detection region to enhance the recognizability of the second trackline 103.

In existing flow cells, the area occupied by tracklines is relatively small, which causes spots on the tracklines to be positioned very close to spots in the sequencing regions. Due to cluster crosstalk, spots in the sequencing regions and spots on the tracklines cannot be effectively distinguished, thereby increasing algorithm difficulty and elevating data error rates. In one embodiment, the present application effectively mitigates cluster crosstalk by increasing the perpendicular distance between the tracklines and sequencing region boundaries.

During the sequencing process, regions where no site is provided, e.g., without pore sites, are dark regions, and regions where sites are provided, e.g., with pore sites, are presented as bright points in the optical image acquired by sequencing, since test samples such as nucleic acid templates are immobilized in the pores. According to the embodiments of the present application, tracklines exhibit a dark-bright-dark periodic pattern. Compared to trackline designs in the existing flow cells, although potential cluster crosstalk may also occur, the tracklines of the present disclosure incorporate fully dark segments to form dashed-line distributions of the whole trackline with distinct bright-dark regions. Additionally, continuous bright points are provided near crossPoints (intersection regions of the first trackline 102 and second trackline 103), such that the crossPoints may be located within bright segments of the tracklines. Therefore, the present application significantly enhances algorithm efficiency and reduces data error rates compared to existing tracklines.

In one embodiment, compared to existing tracklines, the present application increases the spacing distance between tracklines and detection region boundaries, thereby expanding the dark region width between the tracklines and the detection region boundaries. This increases the distance between spots on the tracklines and spots in the sequencing regions. Even with cluster crosstalk, the greater distance between the spots on the tracklines and the spots in the sequencing regions can ensure relatively easy identification of the trackline positions. As a result, the present application significantly enhances algorithm efficiency and reduces data error rates compared to existing tracklines.

Illustratively, each detection region 101 may have dimensions of about 1100 μm×600 μm.

### Polishing Solution

In another aspect of the present application, the present application provides a polishing solution. According to the embodiments of the present application, the polishing solution is used for treating a surface of a substrate having a first polymer bound to the surface thereof, and the polishing solution includes: a polishing agent, selected from at least one of a second polymer and an inorganic nanomaterial. Therefore, using the polishing solution according to the embodiments of the present application can effectively remove the first polymer from the substrate, reducing scratching and corrosion of the substrate and reducing abrasive residues.

It should be noted that the features and advantages described for the polishing solution in the foregoing surface treatment method are also applicable to the polishing solution herein, and details are not repeated herein.

### Reagent Kit

In still another aspect of the present application, the present application provides a reagent kit. According to the embodiments of the present application, the reagent kit includes: the polishing solution described above. Therefore, using the reagent kit according to the embodiments of the present application can effectively remove the first polymer from the substrate, reducing scratching and corrosion of the substrate and reducing abrasive residues.

It should be noted that, in the reagent kit of the present application, all components of the polishing solution can be mixed and stored in the same package, i.e., non-independent package, and can be directly used when required; one or more of the components may also be packaged separately, and used in combination when required according to the instructions accompanying the kit.

It should be noted that the features and advantages described for the polishing solution in the foregoing surface treatment method are also applicable to the polishing solution herein, and details are not repeated herein.

### Flow Cell and Preparation Method Therefor

In still another aspect of the present application, the present application provides a method for preparing a flow cell. According to the embodiments of the present application, the method includes: providing a substrate, where a first polymer is bound to a surface of the substrate; and treating the surface of the substrate having the first polymer bound thereto using the aforementioned surface treatment method, or using the aforementioned polishing solution, to remove the first polymer from at least a portion of the surface of the substrate to obtain the flow cell.

In still another aspect of the present application, the present application provides a flow cell. According to the embodiments of the present application, the flow cell includes a substrate, and the substrate is a substrate treated by the aforementioned surface treatment method, or treated by the aforementioned polishing solution.

As described above, the polishing solution according to the embodiments of the present application can effectively remove the first polymer from the substrate, reducing scratching and corrosion of the substrate and reducing abrasive residues. Therefore, in the flow cell obtained by treating the substrate with the polishing solution, the surface of the substrate in the non-target region does not contain the first polymer, the substrate is free from corrosion or scratches, and no abrasive residue is present. The flow cell demonstrates excellent overall performance and can be used for biological or chemical reactions, such as gene sequencing, thereby enhancing sequencing efficiency and the quality of sequencing data.

It should be noted that the features and advantages described above for the surface treatment method and the polishing solution are also applicable to the flow cell and the preparation method therefor, and details are not repeated herein.

The scheme of the present application will be explained with reference to the following examples. It will be appreciated by those skilled in the art that the following examples are illustrative of the present application only and should not be interpreted as limiting the scope of the present application. The examples without a specified particular technique or condition are performed in accordance with techniques or conditions described in literatures in the art or in accordance with the product specification. The reagents or instruments not provided with manufacturer are conventional and commercially available products.

### Example 1

In this example, a polishing solution was prepared according to the following method:

### 1. Formula

10 wt % of 500 nm nanoscale cerium oxide, 0.5 wt % benzotriazole, 0.5 wt % sodium ethylene diamine tetracetate, 0.3 wt % sodium dodecyl sulfate, 0.2 wt % sodium carbonate, 0.1 wt % bacteriostatic agent Kathon, 1 wt % sodium hexametaphosphate, with deionized water supplemented to 100 wt %, pH of 9.

### 2. Procedure

The nanoscale cerium oxide, sodium dodecyl sulfate, sodium carbonate, bacteriostatic agent Kathon, sodium hexametaphosphate, and deionized water were mixed in sequence to prepare the polishing solution.

### Example 2

In this example, a polishing solution was prepared according to the following method:

### 1. Formula

40 wt % of 40 nm nanoscale silica, 0.5 wt % benzotriazole, 0.1 wt % serine, 0.5 wt % Tween 20, 0.1 wt % Tris, 0.1 wt % bacteriostatic agent Kathon, 1 wt % sodium polyacrylate, with deionized water supplemented to 100 wt %, pH of 9.
2. Procedure
The nanoscale silica, benzotriazole, serine, Tween 20, Tris, bacteriostatic agent Kathon, sodium polyacrylate, and deionized water were mixed in sequence to prepare the polishing solution.

### Example 3

In this example, a polishing solution was prepared according to the following method:

### 1. Formula

40 wt % of 80 nm nanoscale silica, 0.5 wt % benzotriazole, 0.1 wt % serine, 0.5 wt % Tween 20, 0.1 wt % Tris, 0.1 wt % bacteriostatic agent Kathon, 1 wt % sodium polyacrylate, with deionized water supplemented to 100 wt %, pH of 9.

### 2. Procedure

The nanoscale silica, benzotriazole, serine, Tween 20, bacteriostatic agent Kathon, sodium polyacrylate, and deionized water were mixed in sequence to prepare the polishing solution.

### Example 4

In this example, a polishing solution was prepared according to the following method:

### 1. Formula

5 wt % of 800 nm nanoscale poly(ethyl methacrylate) (Shore D hardness of 20 HD), 0.5 wt % benzotriazole, 0.3 wt % lysine, 0.3 wt % Tween 20, 0.01 wt % concentrated hydrochloric acid, 0.1 wt % bacteriostatic agent Kathon, 1 wt % acetic acid, with deionized water supplemented to 100 wt %, pH of 3.

### 2. Procedure

The nanoscale poly(ethyl methacrylate), benzotriazole, lysine, Tween 20, concentrated hydrochloric acid, bacteriostatic agent Kathon, acetic acid, and deionized water were mixed in sequence to prepare the polishing solution.

### Example 5

In this example, a polishing solution was prepared according to the following method:

### 1. Formula

10 wt % of 600 nm nanoscale polystyrene (Shore D hardness of 60 HD), 0.5 wt % benzotriazole, 0.1 wt % glycine, 0.1 wt % Tween 20, 0.1 wt % 0.1 M NaOH, 0.1 wt % bacteriostatic agent Kathon, 1 wt % sodium polyacrylate, with deionized water supplemented to 100 wt %, pH of 9.

### 2. Procedure

The nanoscale polystyrene, benzotriazole, glycine, Tween 20, NaOH, bacteriostatic agent Kathon, sodium polyacrylate, and deionized water were mixed in sequence to prepare the polishing solution.

### Example 6

In this example, a polishing solution was prepared according to the following method:

### 1. Formula

10 wt % of 2 μm nanoscale cerium oxide, 0.5 wt % benzotriazole, 0.5 wt % sodium ethylene diamine tetracetate, 0.3 wt % sodium dodecyl sulfate, 0.2 wt % sodium carbonate, 0.1 wt % bacteriostatic agent Kathon, 1 wt % sodium hexametaphosphate, with deionized water supplemented to 100 wt %, pH of 9.

### 2. Procedure

The nanoscale cerium oxide, sodium dodecyl sulfate, sodium carbonate, bacteriostatic agent Kathon, sodium hexametaphosphate, and deionized water were mixed in sequence to prepare the polishing solution.

### Example 7

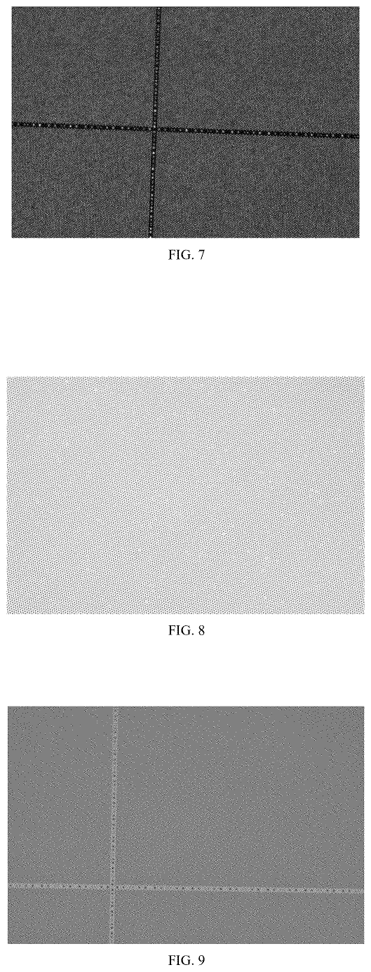

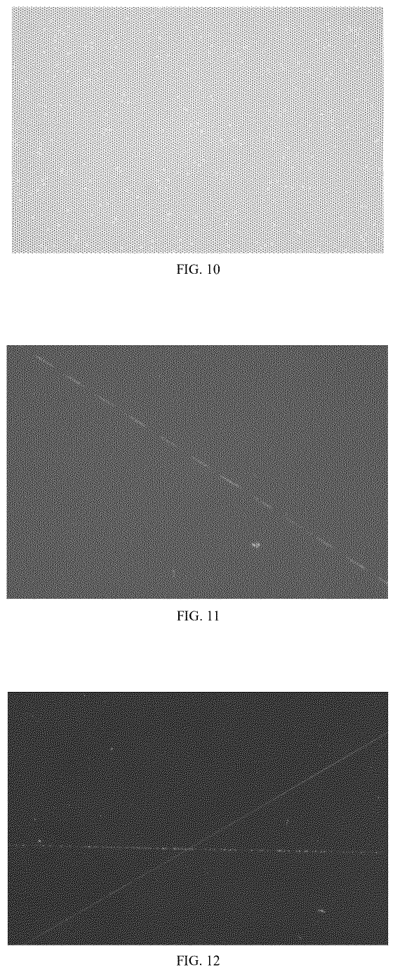

1. The average particle size of the polishing solutions prepared in Examples 1 to 6 was measured using a Nanosizer laser particle analyzer (Malvern).
2. The polishing solutions prepared in Examples 1 to 6 were applied to polish the regions excluding the micropores of the sequencing flow cells. The surface of the substrate of the sequencing flow cell was coated with polyacrylamide hydrogel (Shore D hardness of 30 HD).
The polishing parameters were as follows: Dupont SUBA600 polishing pad, downward pressure 2 psi, platen speed/polishing head speed: 60/80 RPM, polishing time 60 s, and polishing solution flow velocity 200 mL/min.
The polished sequencing flow cells were analyzed for performance as follows:
2.1. The thickness of the soft material on the surface of the sequencing flow cell before and after polishing was measured using a J. A. Woollam M2000 ellipsometer. Removal rate was calculated as the absolute value of the thickness difference of the soft material film before and after polishing divided by the polishing time.
2.2. The surface of the polished sequencing flow cells was examined for fractures using a metallographic microscope at 50×magnification.
2.3. The Ra value of the surface of the polished sequencing flow cells was measured using atomic force microscopy.
2.4. The surface of the polished sequencing flow cells was examined for scratches. Scratch levels 1 to 5 are as follows: 1: no scratches; 2: minor scratches (visible under microscope); 3: multiple scratches (visible to naked eye); 4: extensive scratches; 5: cracks.
The results, shown in Table 1 and FIGS. 7 to 12, demonstrated that the removal rates of the sequencing flow cells polished with the polishing solutions of Examples 1 to 5 were appropriate. The removal rate in Example 6 was slightly higher, which tended to cause substrate thinning, adversely affecting the flatness of the flow cell. Additionally, higher removal rates resulted in increased surface roughness.
No fractures of the sequencing flow cells were observed during polishing with the polishing solution of Examples 1 to 5.
The Ra values of the polished sequencing flow cells of Examples 1 to 4 were appropriate, and no scratches were observed. In Example 5, the higher hardness of the inorganic nanomaterials resulted in minor scratches on the sequencing flow cell (represented by diagonal lines extending from upper left to lower right in FIG. 11), and the Ra value was also slightly elevated. In Example 6, the excessively large particle size of the inorganic nanomaterials resulted in numerous scratches on the surface of the sequencing flow cell (represented by diagonal lines extending from lower left to upper right in FIG. 12, with scratch depths exceeding those in FIG. 11), and the Ra value was relatively high.

TABLE 1
Determination of performance of sequencing
flow cell after polishing

| | Removal | Whether the flow | | |
|---|---|---|---|---|
| Item | rate(Å) | cell is cracked | Ra (nm) | Scratch level |
| Example 1 | 2351 | No | 9.1 | 1 |
| Example 2 | 685 | No | 0.3 | 1 |
| Example 3 | 935 | No | 0.4 | 1 |
| Example 4 | 1326 | No | 8.6 | 1 |
| Example 5 | 1573 | No | 79.3 | 2 |
| Example 6 | 5134 | No | 342.1 | 3 |

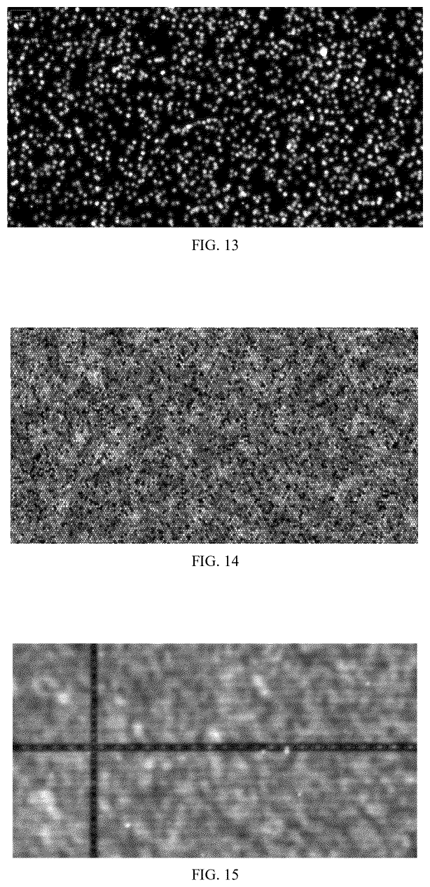

2.5. Sequencing analysis was performed on the sequencing flow cells polished with the polishing solutions of Examples 1 to 6 and sequencing flow cells without polishing treatment. The sequencing image obtained from the flow cells without polishing treatment is shown in FIG. 13, and the sequencing images obtained in the examples were similar, as shown in FIG. 14. It can be seen that in the sequencing images obtained from the sequencing flow cells polished with the polishing solutions, signals within the pores were relatively independent and could be accurately recognized. In contrast, the sequencing images obtained from untreated flow cells exhibited cross-pore interference, resulting in signal redundancy and failed accurate recognition, thereby affecting the sequencing quality.

### Example 8

The polishing solution prepared in Example 1 was applied to polish the regions excluding the micropores of the sequencing flow cell. The trackline structure of the biochip is detailed in FIGS. 3 to 6. In the detection region, the detection sites were configured as circular pore structures with a pore diameter D of 300 nm. The spacing distance a between adjacent detection sites in the X direction was 750 nm, and the spacing distance d between adjacent detection sites in the Y direction was 1300 nm. The spacing distance e between adjacent sites on the first trackline 102 was 750 nm, and the spacing distance f between adjacent sites on the second trackline 103 was 1300 nm. The perpendicular distance g between the boundary of the first trackline 102 and the boundary of the adjacent detection region 101 was 5D, and the perpendicular distance h between the boundary of the second trackline 103 and the boundary of the adjacent detection region 101 was 7D. The pore diameter of the sites on the first trackline 102 was 450 nm, and the pore diameter of the sites on the second trackline 103 was 450 nm.

FIG. 15 is a sequencing image of the biochip according to Example 7. As shown in the figure, the tracklines form distinct alternating bright and dark strips, with significant brightness and darkness contrast in the resulting optical image for easy recognition. This demonstrates that the first polymer outside the micropores can be effectively removed by the polishing method according to the embodiments of the present application.

Reference throughout this specification to “an embodiment”, “one embodiment”, “another embodiment”, “some embodiments”, “an example”, “a specific example”, “another example”, or “some examples”, means that a particular feature, structure, material, or characteristic described in connection with the embodiment or example is included in at least one embodiment or example of the present application. In the specification, the schematic expression of the terms described above does not necessarily refer to the same embodiment or example. Furthermore, the particular features, structures, materials, or characteristics described herein may be combined in any suitable manner in any one or more embodiments or examples. In addition, in the absence of contradiction, those skilled in the art can combine the different embodiments or examples described in this specification or combine the features of different embodiments or examples.

Although the embodiments of the present application have been shown and described above, it will be understood that the embodiments described above are exemplary and are not to be construed as limiting the present application, and that those of ordinary skill in the art may make changes, modifications, replacements, and variations to such embodiments without departing from the scope of the present application.

1-161. (canceled)

162. A surface treatment method, comprising:
using a polishing solution to treat a substrate having a first polymer bound to a surface thereof to remove the first polymer from at least a portion of the surface of the substrate,
wherein the polishing solution comprises a polishing agent, and the polishing agent is selected from at least one of a second polymer and an inorganic nanomaterial,
wherein a Shore D hardness of the first polymer is denoted as A, a Shore D hardness of the second polymer is denoted as B, and A and B satisfy the relationship: B=A±10 HD.

163. The method according to claim 162, wherein the first polymer comprises a polymer gel, and the second polymer is selected from at least one of polystyrene and polymethylmethacrylate.

164. The method according to claim 162, wherein, based on the total weight of the polishing solution being 100%, the weight percentage content of the second polymer is 0.5% to 5.0%.

165. The method according to claim 162, wherein the inorganic nanomaterial is selected from at least one of nanoscale cerium oxide and nanoscale silica, the nanoscale cerium oxide has a particle size selected from 200 nm to 300 nm.

166. The method according to claim 165, wherein the nanoscale silica has a particle size selected from 40 nm to 60 nm.

167. The method according to claim 162, wherein at least one surface of the substrate is provided with micropores, and the first polymer is at least bound to a surface of a portion of regions excluding the micropores,
wherein a surface of the fluid channel is provided with a trackline for partitioning, the trackline comprises a plurality of first tracklines in a first direction and a plurality of second tracklines in a second direction, and the first direction is non-parallel to the second direction, and
wherein each of the first tracklines has first repeating units periodically arranged in the first direction, the first repeating unit comprises a plurality of sites arranged in the first direction, the first repeating unit comprises at least one set of long-period sites, the long-period sites comprise at least three first sites, and a first distance between any two adjacent first sites is equal.

168. The method according to claim 167, wherein the first repeating unit further comprises a second site disposed on a first side of the long-period sites, and a second distance between a first site adjacent to the second site in the long-period sites and the second site is greater than the first distance, wherein the second distance≥the first distance×2.

169. The method according to claim 168, wherein the first repeating unit further comprises a third site disposed on a second side of the long-period sites, and a third distance between a first site adjacent to the third site in the long-period sites and the second site is greater than the first distance,
wherein the third distance≥the first distance×2.

170. The method according to claim 169, wherein the first repeating unit further comprises the third site disposed on the second side of the long-period sites, and the third distance between the first site adjacent to the third site in the long-period sites and the third site is greater than the first distance, wherein the third distance≥the first distance×2.

171. The method according to claim 167, wherein each of the second tracklines has second repeating units periodically arranged in the second direction, the second repeating unit comprises a plurality of sites arranged in the second direction, and the second repeating unit and the first repeating unit are identical or different.

172. The method according to claim 171, wherein the second repeating unit comprises at least one set of short-period sites, the short-period sites consist of one or two sixth sites, and a fifth distance between any two adjacent sixth sites is equal.

173. The method according to claim 172, wherein the second repeating unit further comprises a seventh site disposed on a first side of the short-period sites, and a sixth distance between a sixth site adjacent to the seventh site in the short-period sites and the seventh site is greater than the fifth distance, and wherein the sixth distance≥the fifth distance×2.

174. The method according to claim 171, wherein the second repeating unit further comprises an eighth site disposed on a second side of the short-period sites, and a seventh distance between a sixth site adjacent to the eighth site in the short-period sites and the eighth site is greater than the fifth distance, and wherein the seventh distance≥the fifth distance×2.

175. A polishing solution for treating a surface of a substrate having a first polymer bonded to the surface thereof, the polishing solution comprising:
a polishing agent, selected from at least one of a second polymer and an inorganic nanomaterial,
wherein a Shore D hardness of the first polymer is denoted as A, a Shore D hardness of the second polymer is denoted as B, and A and B satisfy the relationship: B=A±10 HD.

176. The polishing solution according to claim 175, wherein the inorganic nanomaterial is selected from at least one of nanoscale cerium oxide and nanoscale silica, wherein the nanoscale cerium oxide has a particle size selected from 200 nm to 300 nm.

177. The polishing solution according to claim 176, wherein the nanoscale silica has a particle size selected from 40 nm to 60 nm.

178. The polishing solution according to claim 175, wherein, based on the total weight of the polishing solution being 100%, a weight percentage content of the nanoscale cerium oxide is 0.1% to 40.0%.

179. The polishing solution according to claim 175, wherein, based on the total weight of the polishing solution being 100%, a weight percentage content of the nanoscale silica is 0.1% to 50.0%.

180. The polishing solution according to claim 175, wherein the polishing solution has a pH selected from 2 to 11.

181. The polishing solution according to claim 175, wherein the second polymer has a particle size of 200 nm to 800 nm.
